(19) United States
(12) Patent Application Publication
(10) Pub. No.: US 2024/0313552 A1
(43) Pub. Date: Sep. 19, 2024

(54) BATTERY PROTECTION MODE

(71) Applicant: QUALCOMM Incorporated, San Diego, CA (US)

(72) Inventors: Sai Krishna EDIGA, Bangalore (IN); Eric MIKUTEIT, San Diego, CA (US)

(21) Appl. No.: 18/185,528

(22) Filed: Mar. 17, 2023

(51) Int. Cl. H02J 7/00

(52) U.S. Cl. CPC H02J 7/0031; H02J 7/007182

(57) ABSTRACT

Techniques and apparatus for providing battery protection. One example technique for providing battery protection generally includes monitoring a voltage of a battery node during an off mode of a device having a battery coupled to the battery node, determining that the voltage of the battery node is below a first threshold voltage, and disconnecting a path between the battery node and a power supply node of the device in response to the determination.

### TECHNICAL FIELD

Certain aspects of the present disclosure generally relate to power supply circuits, and, more particularly, to techniques and apparatus for battery protection.

### BACKGROUND

Power management integrated circuits (power management ICs or PMICs) are used for managing the electrical power demands of a host system and may include and/or control one or more voltage regulators (e.g., buck converters, charge pumps, or boost converters). A PMIC may be utilized in portable devices (e.g., smartphones, tablets, laptops, wearables, etc.), where power is typically provided by one or more batteries, which may be rechargeable (e.g., via a wired scheme and/or a wireless scheme). In such battery-powered portable devices, the PMIC may be used to control the flow and direction of electrical power in the devices. The PMIC may perform a variety of functions for the device such as DC-to-DC conversion (e.g., using a voltage regulator as described above), battery charging, power-source selection, voltage scaling, power sequencing, overvoltage protection, etc.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed to a method of providing battery protection. The method generally includes monitoring a voltage of a battery node during an off mode of a device having a battery coupled to the battery node, determining that the voltage of the battery node is below a first threshold voltage, and in response to the determination, disconnecting a path between the battery node and a power supply node of the device.

Certain aspects of the present disclosure provide an apparatus. The apparatus generally includes a battery coupled to a battery node, and logic coupled to the battery node. The logic is generally configured to monitor a voltage of the battery node during an off mode of the apparatus, determine that the voltage of the battery node is below a first threshold voltage, and disconnect a path between the battery node and a power supply node of the apparatus, in response to the determination.

Certain aspects of the present disclosure provide an apparatus. The apparatus generally includes a battery coupled to a battery node, means for monitoring a voltage of the battery node during an off mode of the apparatus, means for determining that the voltage of the battery node is below a first threshold voltage, and means for disconnecting a path between the battery node and a power supply node of the apparatus, in response to the determination.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example device that includes a power supply circuit and a battery with protection circuitry, in which aspects of the present disclosure may be implemented.

FIG. 2 is a block diagram of an example power supply circuit that includes a power management integrated circuit (PMIC) and a battery, in which aspects of the present disclosure may be implemented.

FIG. 3A is a plot of an example power supply voltage (VPH) and battery voltage (VBAT) over time during device operation.

FIG. 3B is a plot of example VPH and VBAT over time during device operation, which illustrates entering a battery protection mode when VBAT falls to a battery protection mode (BPM) threshold, in accordance with certain aspects of the present disclosure.

FIG. 4 is a flow diagram of example operations for entering a battery protection mode, in accordance with certain aspects of the present disclosure.

FIG. 5 is a flow diagram of example operations for battery protection, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for protecting a battery of a portable device. An example technique involves monitoring a voltage of a battery node when the device (having a battery coupled to the battery node) enters a shutdown mode (e.g., an off mode) and disconnecting a path between the battery node and a power supply node of the device when the battery node's voltage is below a first threshold voltage (e.g., a battery protection mode (BPM) threshold). The first threshold voltage may be higher than a second threshold voltage (e.g., a protection circuit module (PCM) threshold) for tripping internal protection circuitry of the battery.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatus, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCSs), personal digital assistants (PDAs), and the like.

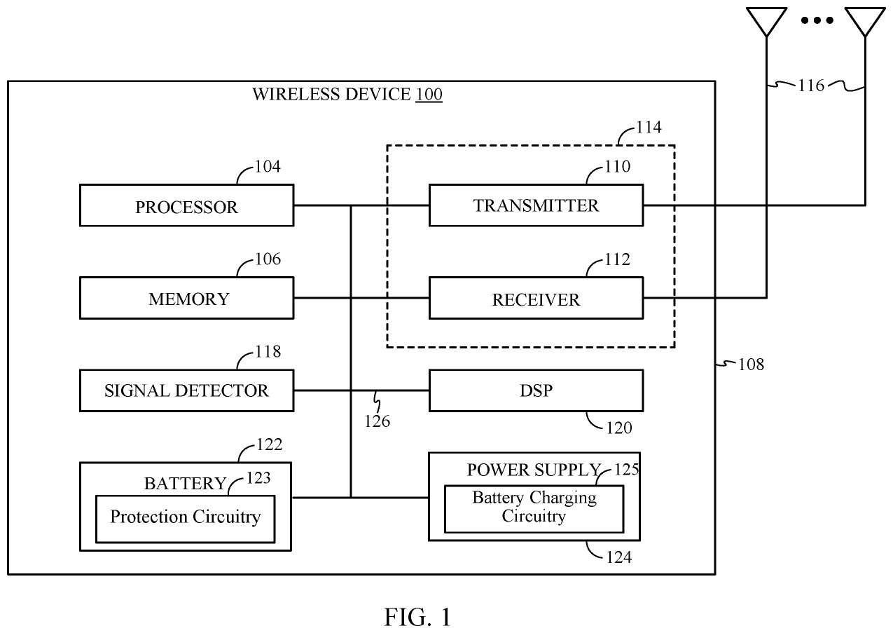

FIG. 1 illustrates an example device 100 in which aspects of the present disclosure may be implemented. The device 100 may be a battery-operated device such as a cellular phone, a personal digital assistant (PDA), a handheld device, a wireless device, a laptop computer, a tablet, a smartphone, an Internet of things (IoT) device, a wearable device, an augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

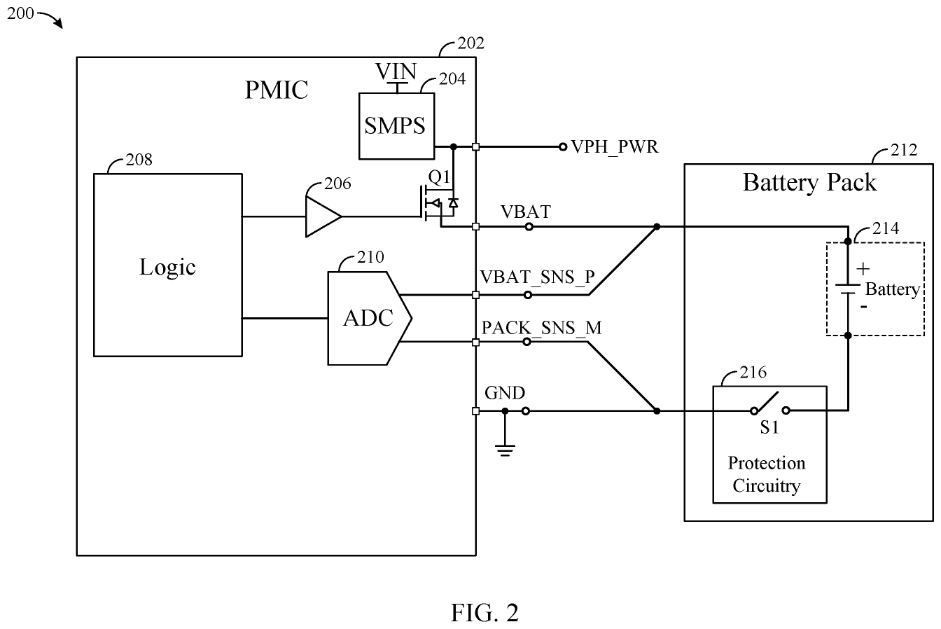

The device 100 may further include a battery 122 used to power the various components of the device 100. The battery 122 may be implemented as a battery pack (e.g., battery pack 212 of FIG. 2). The battery 122 may include protection circuitry 123 (e.g., protection circuitry 216 of FIG. 2) configured to protect the battery 122 from fault events like overcharging, over-discharging, and short-circuiting. The device 100 may also include a power supply circuit 124 for managing the power from the battery to the various components of the device 100. At least a portion of the power supply circuit 124 may be implemented in one or more integrated circuits (power management ICs or PMICs, such as PMIC 202 of FIG. 2). The power supply circuit 124 may perform a variety of functions for the device 100 such as DC-to-DC conversion, battery charging and protection, power-source selection, voltage scaling, power sequencing, etc. For example, the power supply circuit 124 may include battery charging circuitry 125 for charging the battery 122. The battery charging circuitry 125 may be controlled by the power supply circuit 124. The battery charging circuitry 125 may comprise, for example, one or more switched-mode power supplies (SMPSs).

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Power Supply Circuit and Operation

FIG. 2 is a block diagram of an example power supply circuit 200, in which aspects of the present disclosure may implemented. The power supply circuit 200 includes an integrated circuit for power management (e.g., a PMIC 202) and a battery (e.g., a battery 214 of battery pack 212), such as a lithium-ion battery or a battery composed of any of various other suitable battery chemistries. The power supply circuit 200 may be used to provide power for a device (e.g., the device 100), and also to charge the battery when external power (e.g., from a wall adapter or a wireless charger) is provided. As illustrated, the PMIC 202 includes an SMPS circuit 204, a switch, a gate driver 206 (e.g., a buffer), logic 208, and an analog-to-digital (ADC) converter 210. The PMIC 202 may have a number of ports coupled to various nodes. For example, the PMIC 202 may have a port coupled to a power supply node (labeled “VPH_PWR”) providing an internal voltage rail for the device, a port coupled to a battery node (labeled “VBAT”) for coupling to the battery pack 212 (and to the battery 214 therein), a port coupled to a positive battery sense node (labeled “VBAT_SNS_P”) for sensing a voltage of the battery node (VBAT), a port coupled to a negative battery (pack) sense node (labeled “PACK_SNS_M”), and a port coupled to a reference potential node (e.g., electrical ground and labeled “GND”). In certain aspects, the ADC 210 may be implemented as a comparator (an ADC with a resolution of 1 bit).

The SMPS circuit 204 may be used to regulate voltage for the power supply node (VPH_PWR) when external power is provided and/or to charge the battery 214. The SMPS circuit 204 may be implemented by any of various suitable SMPS circuit topologies, such as a buck converter, a boost converter, a buck-boost converter, or a charge pump. The SMPS circuit 204 has an output coupled to the VPH_PWR node and to a drain of the transistor Q1. An input of the SMPS circuit 204 may be coupled to an input voltage node (labeled “VIN”). The VIN node may serve as the power supply rail for the SMPS circuit 204.

The switch may be implemented by a transistor (e.g., transistor Q1, as shown in FIG. 2), a relay, or any of various other suitable components or combinations of components for selective coupling. In certain aspects, transistor Q1 may be an n-type transistor, and the transistor Q1 may have a source coupled to the VBAT node, as depicted. The transistor Q1 may be referred to as a battery field-effect transistor (BATFET). The gate of transistor Q1 may be coupled to an output of the logic 208 through the gate driver 206. The transistor Q1 may be configured to operate as a switch, selectively forming a path between the VPH_PWR node and the VBAT node. For example, when the transistor Q1 is turned on (e.g., activated, such that the switch is closed), the VPH_PWR node and the VBAT node may be connected, and when the transistor Q1 is open (e.g., deactivated, such that the switch is open), the VPH_PWR node and the VBAT node are disconnected. In certain scenarios, the battery 214 may be charged through the transistor Q1 when the transistor is activated.

The logic 208 may control operation of the SMPS circuit 204 and/or other aspects of the power supply circuit 200. The logic 208 may have an output coupled to the gate driver 206 and an input coupled to an output of the ADC 210. The logic 208 may control operation of the transistor Q1 via an output signal to the input of the gate driver 206. In some cases, the PMIC 202 may also include one or more multiplexers (not shown) coupled between one or more ports of the PMIC 202 (e.g., port coupled to the VPH_PWR node, port coupled to the VBAT node) and the inputs of the ADC 210. The VBAT_SNS_P node and the PACK_SNS_M node may both be coupled as a differential input pair to the ADC 210. The VBAT_SNS_P node may be coupled to the VBAT node (e.g., remotely at or near the positive terminal of the battery 214 when the battery pack 212 is connected to the PMIC), and the PACK_SNS_M node may be coupled to the reference potential node (e.g., remotely at or near the negative terminal of the battery pack 212 when the battery pack 212 is connected to the PMIC and/or to the GND node for the power supply circuit).

The battery pack 212 may include protection circuitry 216 (also referred to as a “protection circuit module (PCM)”) coupled in series with the battery 214. The battery 214 may represent a single-cell (1S) battery, a two-cells-in-series (2S) battery, or more than two stacked (e.g., in series) battery cells in a battery (e.g., a multi-cell-in series battery). The battery 214 may also represent multiple batteries. The positive terminal of the battery 214 may be coupled to a positive terminal of the battery pack 212, which may be coupled to the VBAT node and the VBAT_SNS_P node, as depicted. The negative terminal of the battery 214 may be coupled to the negative terminal of the battery pack 212, which may be coupled to the PACK_SNS_M node and the GND node, as depicted. In some cases, the negative terminal of the battery 214 may be coupled to the negative terminal of the battery pack 212 via the protection circuitry 216, also as depicted. In other cases, the protection circuitry 216 may be coupled between the positive terminal of the battery 214 and the positive terminal of the battery pack 212. In other words, the protection circuitry 216 may be coupled to the positive (e.g., high) side of the battery pack 212, or to the negative (e.g., low) side of the battery pack 212.

The protection circuitry 216 may include one or more switches, such as switch S1, for protecting the battery 214 when certain conditions (e.g., fault conditions) are detected. For example, these conditions may include overcharging, over-discharging, short-circuiting, and over-draining, to prevent the battery pack from explosion, fire, or other damage. When the switch S1 of the protection circuitry 216 is closed and the PMIC 202 is coupled to the battery pack 212, the negative terminal of the battery 214 is coupled to the PACK_SNS_M node and the GND node, and when the switch S1 is open, the negative terminal of the battery is decoupled from the PACK_SNS_M node and the GND node.

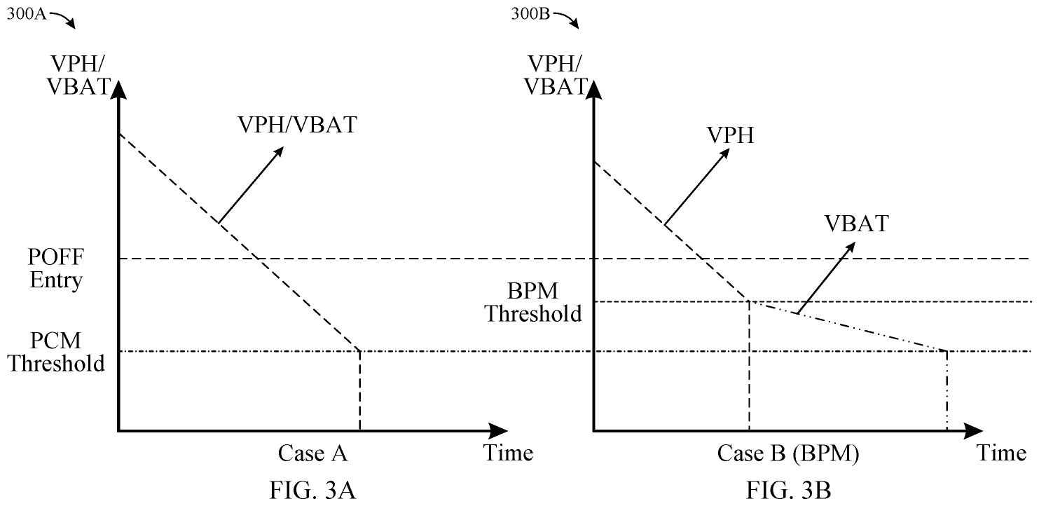

FIG. 3A is a plot 300A of an example power supply voltage (VPH) and a battery voltage (VBAT) over time during device operation, in accordance with certain aspects of the present disclosure. When external power is not provided to the portable device, the power supply circuit 200 may be configured to provide electrical power from the battery 214 to the VPH_PWR node (through the VBAT node and the activated transistor Q1) for powering one or more circuits of the device. During normal device use, the VPH voltage at the VPH_PWR node and the VBAT node (shorted together) will decrease due to electrical power being drawn from the battery 214 to power the device. The dashed line labeled “POFF entry” represents the VPH/VBAT voltage level when the device 100 enters an off mode (e.g., as a result of a user shutting down a device, a device having a low battery voltage, or any other fault) and is powered off. However, even when the device 100 is in the off mode and unused, the battery 214 will continue to be drained, and the VPH/VBAT voltage continues to decrease over time, as shown. In some cases, the device may remain in off mode without being charged for long periods of time. The protection circuitry 216 may be configured to detect undervoltage in the battery 214, and to open the switch S1 to avoid battery over-draining when the VBAT voltage (and the VPH voltage) reaches an undervoltage threshold represented by the dashed line labeled “PCM Threshold” for protection circuit module (PCM) threshold. When the switch S1 is opened, the VPH/VBAT voltage drops to zero volts, as depicted.

In some cases, when a user attempts to power on the device (with or without charging the battery) after the undervoltage condition was detected and the switch S1 has been opened, the protection circuitry 216 may fail to reset, and thus, the battery 214 may not recharge, such that the device may be unable to power on with this battery pack 212. For example, the protection circuitry 216 may be unable to close switch S1 to allow the device to turn on (e.g., by being unable to attain the minimum release voltage to close switch S1), and device operation may be impossible without charging. In another example, even after charging of the device for a long time, the device may still fail to turn on (e.g., by being unable to attain the minimum release voltage to close switch S1).

### Example Operations for Entering Battery Protection Mode

Certain aspects of the present disclosure provide techniques and apparatus for providing battery protection for a power supply circuit of a device when the device enters the off mode. Such techniques involve monitoring a battery voltage and enabling a protection mode in response to a detected condition. For example, a power supply circuit may enter protection mode and effectively decouple the battery from the device when the battery voltage approaches an undervoltage level. As a result, the power supply circuit of the device may be able to avoid tripping the protection circuitry of the battery (e.g., avoid reaching the PCM threshold), thereby providing for recovery from operating in the off mode for much longer than conventional implementations (e.g., increased shelf-life).

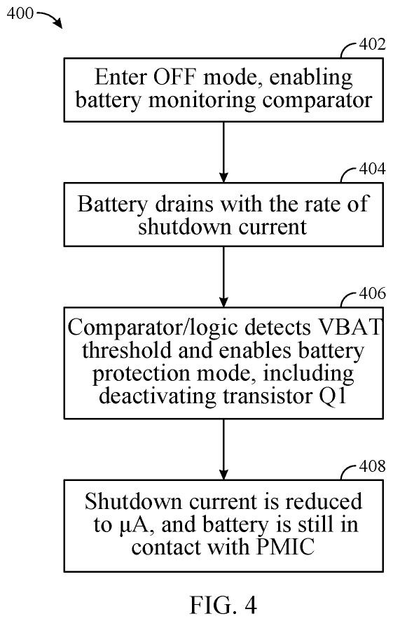

FIG. 4 is flow diagram of example operations 400 for entering the protection mode, in accordance with certain aspects of the present disclosure. The operations 400 may be performed, for example, by a power supply circuit, such as the power supply circuit 200 of FIG. 2, or more specifically in certain aspects by an integrated circuit (IC), such as the PMIC 202, which may be included in the power supply circuit 200 of FIG. 2.

The operations 400 may begin, at block 402, by enabling an ADC (e.g., the ADC 210, which may be implemented as a battery monitoring comparator) when the device enters the off mode. FIG. 3B is a plot 300B of example power supply voltage (VPH) and battery voltage (VBAT) over time during device operation along with a battery protection threshold (labeled “BPM Threshold” for battery protection mode threshold), in accordance with certain aspects of the present disclosure. It is noted that the time axis of plot 300B may not be to scale. The ADC 210 may begin to monitor the VBAT voltage (e.g., the voltage difference between the VBAT_SNS_P and PACK_SNS_M nodes or the voltage difference between the VBAT and GND nodes) when the device enters the off mode. For example, the ADC (e.g., the comparator) may begin to compare the VBAT voltage to the BPM threshold when the device enters the off mode.

At block 404, the VBAT voltage may decrease as the battery drains based on the rate of shutdown current while the device is operating in off mode. At block 406, the comparator and/or the logic (e.g., the logic 208) may detect when the VBAT voltage reaches the BPM threshold (e.g., based on when the comparator output changes logic levels). In certain aspects, the BPM threshold may be adjustable. For example, the BPM threshold may be programmable via the PMIC 202 (e.g., via the logic 208). The BPM threshold should be higher than the PCM threshold of the power supply circuit 200. For example, the BPM threshold may be a few millivolts (e.g., 50 mV to 100 mV) higher than the PCM threshold. In this manner, tripping the protection circuitry (as a result of the VBAT voltage dropping to the PCM threshold) may be avoided, or at least delayed for a longer period of time, as illustrated in the plot 300B, because the battery drains with its own leakage current after this point, rather than due to shutdown current from device circuitry coupled to the VPH_PWR node.

When the VBAT voltage reaches the BPM threshold, the logic 208 may cause the power supply circuit 200 to enter a battery protection mode. Entering the battery protection mode may involve disconnecting the VPH_PWR node from the VBAT node (e.g., severing the path between the VPH_PWR node and the VBAT node formed by the transistor Q1). For example, entering the battery protection mode may involve the logic 208 deactivating the transistor Q1, which effectively disconnects the VPH_PWR node from the VBAT node. In some cases, entering the battery protection mode may also include the logic 208 reverse biasing a body diode of the transistor Q1. In some cases, operating in the battery protection mode and avoiding tripping the protection circuitry 216 may extend the shelf-life of the battery 214, as described above.

At block 408, after the battery protection mode has been entered, the shutdown current of the power supply circuit 200 may be reduced (e.g., reduced to microamperes (μA)), yet the battery 214 may still be coupled to the PMIC 202 (unlike in the case when the protection circuitry 216 is enabled and the switch S1 is opened). For example, the PMIC 202 may remain coupled to the battery 214 via the VBAT node, the VBAT_SNS_P node, the PACK_SNS_M node, and the GND node, such that the PMIC may still be able to sense various parameters of the battery during the off mode (and can control charging of the battery if the device exits the off mode and the transistor Q1 is activated).

As illustrated in the plot 300B, the VPH voltage may drop to zero after the battery protection mode is enabled at block 406, while the VBAT voltage may continue to decrease (with a different, shallower slope) at block 408 until the PCM threshold is reached (or external power is provided to charge the battery 214). The rate of decline of the VBAT voltage after the battery protection mode is enabled may be significantly smaller than the rate of decline before the protection mode is enabled, due to the drastically reduced shutdown current after the battery protection mode is enabled. In other words, the life of the battery 214 (e.g., the length of time before the VBAT voltage reaches the PCM threshold) is greatly extended after engaging the protection mode. Operating in the battery protection mode may permit the battery 214 to avoid the battery drainage that often occurs during the off mode when the VPH_PWR node is connected to the VBAT node. In addition, entering the battery protection mode may also enable the device powered by the battery 214 to react to a user input (e.g., by displaying a low battery indicator) after a long period of time spent in the off mode and may avoid, or at least reduce the chances of, a non-recoverable dead battery scenario.

Operating in the battery protection mode may also ensure that the device powered by the battery 214 remains capable of charging when provided with an external power source. In certain aspects, when the external power source is provided and the battery 214 begins charging while the battery protection mode is enabled, the battery 214 may be configured to skip a pre-charge mode and enter a constant current mode, allowing the battery 214 to charge more rapidly (e.g., as a result of the elevated VBAT voltage, compared to conventional implementations).

### Example Operations for Battery Protection

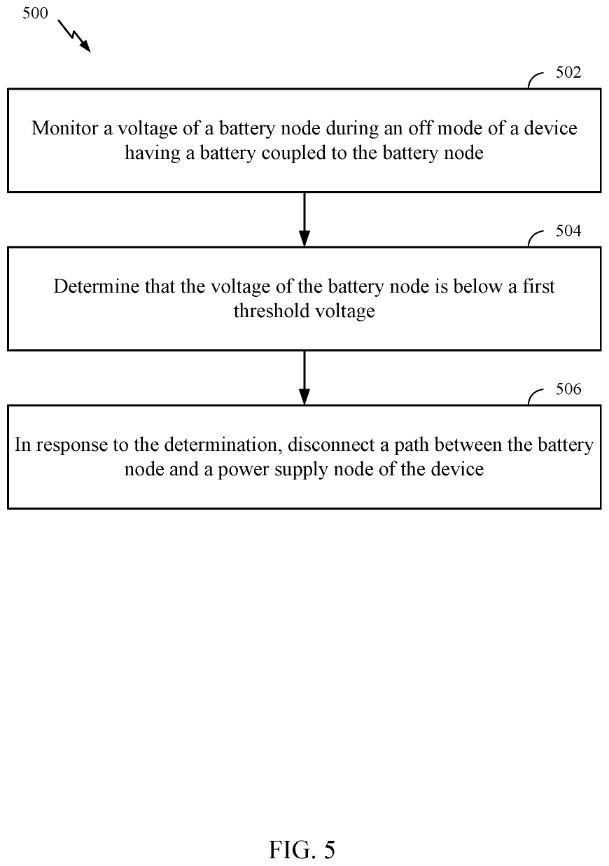

FIG. 5 is a flow diagram of example operations 500 for battery protection, in accordance with certain aspects of the present disclosure. The operations 500 may be performed by an apparatus (e.g., the device 100 of FIG. 1) configured to be powered by a battery, or more specifically in certain aspects, by a power management integrated circuit (PMIC) (e.g., PMIC 202) of the apparatus.

The operations 500 may generally include, at block 502, monitoring a voltage of a battery node (e.g., the VBAT node) during an off mode of a device (e.g., device 100) having a battery (e.g., battery 122) coupled to the battery node. The battery may be a battery pack (e.g., battery pack 212) comprising one or more battery cells (e.g., battery 214) and protection circuitry (e.g., protection circuitry 216) coupled in series with at least one of the battery cells. In certain aspects, the monitoring at block 502 begins when the device enters the off mode.

According to certain aspects, the operations 500 may further include, at block 504, determining that the voltage of the battery node is below a first threshold voltage (e.g., a BPM threshold). In some cases, the determining involves comparing the voltage of the battery node to the first threshold voltage with a comparator or with logic and an ADC (e.g., ADC 210). In certain aspects, the first threshold voltage is programmable.

According to certain aspects, the operations 500 may further include, at block 506, disconnecting a path between the battery node and a power supply node (e.g., the VPH_PWR node) of the device, in response to the determination. In some cases, the disconnecting occurs before the protection circuitry can detect that the voltage of the battery node is below a second threshold voltage (e.g., the PCM threshold) and open circuit the at least one of the battery cells from the power supply node of the device. The second threshold voltage may be lower than the first threshold voltage. In certain cases, the operations 500 may avoid tripping the protection circuitry due to an undervoltage condition of the battery. For example, the operations 500 may avoid tripping the protection circuitry by disconnecting the path between the battery node and the power supply node before the voltage of the battery node falls to the second threshold voltage.

In some cases, the disconnecting at block 506 involves opening a switch (e.g., turning off the transistor Q1) coupled between the power supply node and the battery node. According to certain aspects, the operations 500 may further include charging the battery through the switch when the switch is closed.

### Example Aspects

In addition to the various aspects described above, specific combinations of aspects are within the scope of the disclosure, some of which are detailed below:

Aspect 1: A method of battery protection, comprising: monitoring a voltage of a battery node during an off mode of a device having a battery coupled to the battery node; determining that the voltage of the battery node is below a first threshold voltage; and in response to the determination, disconnecting a path between the battery node and a power supply node of the device.

Aspect 2: The method of Aspect 1, wherein the battery is a battery pack comprising one or more battery cells and protection circuitry coupled in series with at least one of the battery cells.

Aspect 3: The method of Aspect 2, wherein the disconnecting occurs before the protection circuitry can detect that the voltage of the battery node is below a second threshold voltage, lower than the first threshold voltage, and open circuit the at least one of the battery cells from the power supply node or a reference potential node of the device.

Aspect 4: The method of Aspect 2 or 3, wherein tripping the protection circuitry is avoided.

Aspect 5: The method according to any of Aspects 1-4, wherein the disconnecting comprises opening a switch coupled between the power supply node and the battery node.

Aspect 6: The method of Aspect 5, further comprising charging the battery through the switch when the switch is closed.

Aspect 7: The method according to any of Aspects 1-6, wherein the monitoring begins when the device enters the off mode.

Aspect 8: The method according to any of Aspects 1-7, wherein the determining comprises comparing the voltage of the battery node to the first threshold voltage with a comparator.

Aspect 9: The method according to any of Aspects 1-8, wherein the first threshold voltage is programmable.

Aspect 10: An apparatus comprising: a battery coupled to a battery node; and logic coupled to the battery node and configured to: monitor a voltage of the battery node during an off mode of the apparatus; determine that the voltage of the battery node is below a first threshold voltage; and disconnect a path between the battery node and a power supply node of the apparatus, in response to the determination.

Aspect 11: The apparatus of Aspect 10, wherein the battery is a battery pack comprising one or more battery cells and protection circuitry coupled in series with at least one of the battery cells.

Aspect 12: The apparatus of Aspect 11, wherein to disconnect the path, the logic is configured to disconnect the path before the protection circuitry can detect that the voltage of the battery node is below a second threshold voltage, lower than the first threshold voltage, and open circuit the at least one of the battery cells from the power supply node or a reference potential node of the apparatus.

Aspect 13: The apparatus of Aspect 11 or 12, wherein the logic is further configured to avoid tripping the protection circuitry due to an undervoltage condition of the battery.

Aspect 14: The apparatus according to any of Aspects 10-13, further comprising a switch coupled between the power supply node and the battery node, wherein to disconnect the path, the logic is configured to open the switch.

Aspect 15: The apparatus of Aspect 14, wherein the logic is further configured to charge the battery through the switch when the switch is closed.

Aspect 16: The apparatus according to any of Aspects 10-15, wherein the logic is configured to begin monitoring the voltage of the battery node when the apparatus enters the off mode.

Aspect 17: The apparatus according to any of Aspects 10-16, further comprising a comparator including an output coupled to an input of the logic, including a first input coupled to the battery node, and including a second input coupled to a reference voltage node configured to have the first threshold voltage.

Aspect 18: The apparatus according to any of Aspects 10-17, wherein the first threshold voltage is programmable.

Aspect 19: An apparatus comprising: a battery coupled to a battery node; means for monitoring a voltage of the battery node during an off mode of the apparatus; means for determining that the voltage of the battery node is below a first threshold voltage; and means for disconnecting a path between the battery node and a power supply node of the apparatus, in response to the determination.

Aspect 20: The apparatus of Aspect 19, wherein: the battery is a battery pack comprising one or more battery cells and protection circuitry coupled in series with at least one of the battery cells; and the means for disconnecting is configured to disconnect the path before the protection circuitry can detect that the voltage of the battery node is below a second threshold voltage, lower than the first threshold voltage, and open circuit the at least one of the battery cells from the power supply node or a reference potential node of the apparatus.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or a processor. Generally, where there are operations illustrated in figures, those operations may have corresponding counterpart means-plus-function components with similar numbering. For example, means for monitoring and/or means for determining may include logic (e.g., logic 208 as illustrated in FIG. 2) and/or an analog-to-digital converter (ADC) (e.g., ADC 210 as depicted in FIG. 2), such as a comparator (also considered as a 1-bit ADC). Means for disconnecting may include a control circuit (e.g., logic 208 as shown in FIG. 2) and/or a switch, which may be implemented by a transistor (e.g., transistor Q1 as portrayed in FIG. 2).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A method of battery protection, comprising:
monitoring a voltage of a battery node during an off mode of a device having a battery coupled to the battery node;
determining that the voltage of the battery node is below a first threshold voltage; and
in response to the determination, disconnecting a path between the battery node and a power supply node of the device.

2. The method of claim 1, wherein the battery is a battery pack comprising one or more battery cells and protection circuitry coupled in series with at least one of the battery cells.

3. The method of claim 2, wherein the disconnecting occurs before the protection circuitry can detect that the voltage of the battery node is below a second threshold voltage, lower than the first threshold voltage, and open circuit the at least one of the battery cells from the power supply node or a reference potential node of the device.

4. The method of claim 2, wherein tripping the protection circuitry is avoided.

5. The method of claim 1, wherein the disconnecting comprises opening a switch coupled between the power supply node and the battery node.

6. The method of claim 5, further comprising charging the battery through the switch when the switch is closed.

7. The method of claim 1, wherein the monitoring begins when the device enters the off mode.

8. The method of claim 1, wherein the determining comprises comparing the voltage of the battery node to the first threshold voltage with a comparator.

9. The method of claim 1, wherein the first threshold voltage is programmable.

10. An apparatus comprising:
a battery coupled to a battery node; and
logic coupled to the battery node and configured to:
monitor a voltage of the battery node during an off mode of the apparatus;
determine that the voltage of the battery node is below a first threshold voltage; and
disconnect a path between the battery node and a power supply node of the apparatus, in response to the determination.

11. The apparatus of claim 10, wherein the battery is a battery pack comprising one or more battery cells and protection circuitry coupled in series with at least one of the battery cells.

12. The apparatus of claim 11, wherein to disconnect the path, the logic is configured to disconnect the path before the protection circuitry can detect that the voltage of the battery node is below a second threshold voltage, lower than the first threshold voltage, and open circuit the at least one of the battery cells from the power supply node or a reference potential node of the apparatus.

13. The apparatus of claim 11, wherein the logic is further configured to avoid tripping the protection circuitry due to an undervoltage condition of the battery.

14. The apparatus of claim 10, further comprising a switch coupled between the power supply node and the battery node, wherein to disconnect the path, the logic is configured to open the switch.

15. The apparatus of claim 14, wherein the logic is further configured to charge the battery through the switch when the switch is closed.

16. The apparatus of claim 10, wherein the logic is configured to begin monitoring the voltage of the battery node when the apparatus enters the off mode.

17. The apparatus of claim 10, further comprising a comparator including an output coupled to an input of the logic, including a first input coupled to the battery node, and including a second input coupled to a reference voltage node configured to have the first threshold voltage.

18. The apparatus of claim 10, wherein the first threshold voltage is programmable.

19. An apparatus comprising:
a battery coupled to a battery node;
means for monitoring a voltage of the battery node during an off mode of the apparatus;
means for determining that the voltage of the battery node is below a first threshold voltage; and
means for disconnecting a path between the battery node and a power supply node of the apparatus, in response to the determination.

20. The apparatus of claim 19, wherein:
the battery is a battery pack comprising one or more battery cells and protection circuitry coupled in series with at least one of the battery cells; and
the means for disconnecting is configured to disconnect the path before the protection circuitry can detect that the voltage of the battery node is below a second threshold voltage, lower than the first threshold voltage, and open circuit the at least one of the battery cells from the power supply node or a reference potential node of the apparatus.
